(19) United States
(12) Patent Application Publication
(10) Pub. No.: US 2020/0283620 A1
(43) Pub. Date: Sep. 10, 2020

(54) RESIN COMPOSITION

(71) Applicant: AJINOMOTO CO., INC., Tokyo (JP)

(72) Inventors: Hiroyuki SAKAUCHI, Kawasaki-shi (JP); Minoru SASAKI, Kawasaki-shi (JP); Mariko MIYOSHI, Kawasaki-shi (JP)

(73) Assignee: AJINOMOTO CO., INC., Tokyo (JP)

(21) Appl. No.: 16/809,747

(22) Filed: Mar. 5, 2020

(30) Foreign Application Priority Data
Mar. 7, 2019 (JP) 2019-041947

(51) Int. Cl. C08L 63/04; C08G 59/22; C08G 59/24; C08G 59/28; C08K 3/013; C08K 3/04; C08K 3/36; C08K 5/07; H01L 23/06

(52) U.S. Cl. CPC C08L 63/04; C08G 59/226; C08G 59/245; C08G 59/28; C08L 2203/206; C08K 3/04; C08K 3/36; C08K 5/07; H01L 23/06; C08K 3/013

(57) ABSTRACT

Resin compositions including (A) an epoxy resin, (B) a curing agent, and (C) an inorganic filler, in which a chloride ion content included in the resin composition measured in accordance with a sample combustion ion chromatography method (BS EN 14582 2007) is 50 ppm or less are capable of forming a cured product having excellent adhesion with a conductive layer even after the HAST test.

### CROSS REFERENCES TO RELATED APPLICATIONS

This application claims priority to Japanese Patent Application No. 2019-041947, filed on Mar. 7, 2019, which is incorporated herein by reference in its entirety.

### BACKGROUND OF THE INVENTION

### Field of the Invention

The present invention relates to resin compositions. In addition, the present invention relates to circuit boards and semiconductor chip packages made from such a resin composition.

### Discussion of the Background

In recent years, demands for highly functional electronic small devices such as a smartphone and a tablet type device are increasing. With such a trend, an insulating material which can be used as a sealing layer and as an insulating layer of these small electronic devices is required to be highly functional as well. As the insulating material like this, a resin composition that is shaped by curing has been known (for example, see Japanese Patent Application Laid-open No. 2013-237715 and Japanese Patent No. 6288344, which are incorporated herein by reference in their entireties).

However, there remains a need for improved insulating materials

### SUMMARY OF THE INVENTION

The present inventors investigated a resin composition which can form a sealing layer and an insulating layer; and as a result, it was found that when an inorganic filler is included in the resin composition, usually a coefficient of thermal expansion (sometimes this is called “CTE”) can be lowered, but adhesion between an insulating layer and a conductive layer such as copper foil decreases upon carrying out an environmental test under a high temperature and high humidity environment (HAST test).

The present invention was conceived in view of the above-mentioned problem.

Accordingly, it is one object of the present invention to provide novel resins compositions.

It is another object of the present invention to provide novel resin compositions which are capable of forming a cured product having excellent adhesion with a conductive layer even after the HAST test.

It is another object of the present invention to provide novel circuit boards and semiconductor chip packages made from such a resin composition.

These and other objects, which will become apparent during the following detailed description, have been achieved by the inventors' discovery that that when a chloride ion content included in the resin composition was made below a certain value, a cured product having excellent adhesion with a conductive layer even after the HAST test could be obtained.

Thus, the present invention includes the following embodiments.

(1) A resin composition comprising:
(A) an epoxy resin,
(B) a curing agent, and
(C) an inorganic filler, wherein

a chloride ion content included in the resin composition measured in accordance with a sample combustion ion chromatography method (BS EN 14582 2007) is 50 ppm or less.

(2) The resin composition according to (1), wherein a content of the (C) component is 80% or more by mass when non-volatile components in the resin composition is taken as 100% by mass.

(3) The resin composition according to (1) or (2), wherein coefficient of thermal expansion of a cured product obtained by thermally curing the resin composition at 180° C. for 90 minutes is 15 ppm or less.

(4) The resin composition according to any one of (1) to (3), wherein the (B) component comprises an acid anhydride curing agent.

(5) The resin composition according to any one of (1) to (4), wherein the resin composition is in a state of liquid.

(6) The resin composition according to any one of (1) to (5), wherein the resin composition is used for sealing or for an insulating layer.

(7) A circuit board comprising an insulating layer formed of a cured product of the resin composition according to any one of (1) to (6).

(8) A semiconductor chip package comprising the circuit board according to (7) and a semiconductor chip installed on the circuit board.

(9) A semiconductor chip package comprising a semiconductor chip and a cured product of the resin composition according to any one of (1) to (6) to seal the semiconductor chip.

### Advantageous Effects of Invention

According to the present invention, what can be provided are: a resin composition capable of forming a cured product having excellent adhesion with a conductive layer even after the HAST test; and a circuit board and a semiconductor chip package using this resin composition.

### DETAILED DESCRIPTION OF THE PREFERRED EMBODIMENTS

Hereinafter, the present invention will be explained in detail by means of embodiments and examples. However, the present invention is not limited to the embodiments and examples described hereinafter; and thus, the invention can be carried out in an arbitrarily changed manner thereof so far as the change is within the range of the claims of the present invention as well as within an equivalent range thereof. Here, “ppm” is on the mass basis unless otherwise specifically mentioned.

### Resin Composition

The resin composition of the present invention includes (A) an epoxy resin, (B) a curing agent, and (C) an inorganic filler, in which a chloride ion content included in the resin composition is 50 ppm or less as measured in accordance with a sample combustion ion chromatography method (BS EN 14582 2007). When the chloride ion content included in the resin composition is made to 50 ppm or less, a cured product having excellent adhesion with a conductive layer such as copper foil even after the HAST test can be obtained.

As described before, when a content of the inorganic filler in the resin composition is increased, the coefficient of thermal expansion can be decreased, but this causes a decrease in the adhesion with the conductive layer after the HAST test.

However, as a result of an extensive investigation by the inventors of the present invention, when the chloride ion content included in the resin composition is made to 50 ppm or less, it became possible to enhance the adhesion with the conductive layer after the HAST test.

The inventors of the present invention presumes a following mechanism with which the excellent merit as described above can be obtained when the chloride ion content included in the resin composition is made to 50 ppm or less. Here, it must be noted that the technical scopes of the present invention are not restricted by the mechanism explained below.

In the (A) component, epichlorohydrin can be included as an impure substance. When this epichlorohydrin is removed, corrosion of the conductive layer such as copper foil due to the chloride ion of epichlorohydrin can be suppressed. As a result, the cured product having an excellent adhesion with the conductive layer even after the HAST test can be obtained.

Because of this, the coefficient of thermal expansion can be lowered even by increasing the content of the inorganic filler in the resin composition, so that the present invention is excellent as well in that this can be compatible with the increase in the adhesion with the conductive layer after the HAST test.

In addition, the resin composition may further include an arbitrary component with the combination of (A) to (C). Examples of the arbitrary component include (D) a curing accelerator and (E) other additives. Hereinafter, these components included in the resin composition of the present invention will be explained in detail.

### (A) Epoxy Resin

The resin composition contains (A) an epoxy resin as the (A) component. Examples of the (A) epoxy resin include a bixylenol epoxy resin, a bisphenol A epoxy resin, a bisphenol F epoxy resin, a bisphenol S epoxy resin, a bisphenol AF epoxy resin, a dicyclopentadiene epoxy resin, a trisphenol epoxy resin, a naphthol novolak epoxy resin, a phenol novolak epoxy resin, a tert-butyl-catechol epoxy resin, a naphthalene epoxy resin, a naphthol epoxy resin, an anthracene epoxy resin, a glycidyl amine epoxy resin, a glycidyl ester epoxy resin, a cresol novolak epoxy resin, a biphenyl epoxy resin, a linear aliphatic epoxy resin, an epoxy resin having a butadine structure, an alicyclic epoxy resin, a heterocyclic epoxy resin, an epoxy resin having a Spiro ring, a cyclohexane epoxy resin, a cyclohexane dimethanol epoxy resin, a naphthylene ether epoxy resin, a trimethylol epoxy resin, and a tetraphenylethane epoxy resin. The epoxy resin may be used alone or in combination of two or more kinds thereof.

It is preferable that the resin composition contains, as the (A) epoxy resin, an epoxy resin having two or more epoxy groups in one molecule thereof. In order to clearly obtain the intended effects of the present invention, the ratio of the epoxy resin having two or more epoxy groups in one molecule thereof is preferably 50% or more by mass, more preferably 60% or more by mass, while especially preferably 70% or more by mass, on the basis of 100% by mass of the non-volatile components in the (A) epoxy resin.

The epoxy resin is classified into the epoxy resin that is in the state of liquid at 20° C. (hereinafter, this is sometimes called “liquid epoxy resin”) and the epoxy resin that is in the state of solid at 20° C. (hereinafter, this is sometimes called “solid epoxy resin”). In the resin composition, as the (A) epoxy resin, any one of the liquid epoxy resin and the solid epoxy resin, or a combination of the liquid epoxy resin and the solid epoxy resin may be used. Among them, in view of lowering viscosity of the resin composition, the liquid epoxy resin is preferably used.

As the liquid epoxy resin, a liquid epoxy resin having two or more epoxy groups in one molecule thereof is preferable.

The liquid epoxy resin is preferably a bisphenol A epoxy resin, a bisphenol F epoxy resin, a bisphenol AF epoxy resin, a naphthalene epoxy resin; a glycidyl ester epoxy resin, a glycidyl amine epoxy resin, a phenol novolak epoxy resin, an alicyclic epoxy resin such as an alicyclic epoxy resin having an ester skeleton, a cyclohexane epoxy resin, a cyclohexane dimethanol epoxy resin, a glycidyl amine epoxy resin, and an epoxy resin having a butadine structure. The liquid epoxy resin is more preferably a glycidyl amine epoxy resin, a bisphenol A epoxy resin, a bisphenol F epoxy resin, and an alicyclic epoxy resin.

Specific examples of the liquid epoxy resin include “HP4032”, “HP4032D”, and “HP4032SS” (all are naphthalene epoxy resins manufactured by DIC Corp.); “828US”, “jER828EL”, “825”, and “Epikote 828EL” (all are bisphenol A epoxy resins manufactured by Mitsubishi Chemical Corp.); “jER807” and “1750” (both are bisphenol F epoxy resins manufactured by Mitsubishi Chemical Corp.); “jER152” (phenol novolak epoxy resin manufactured by Mitsubishi Chemical Corp.); “630” and “630LSD” (both are glycidyl amine epoxy resins manufactured by Mitsubishi Chemical Corp.); “ZX1059” (mixture of a bisphenol A epoxy resin and a bisphenol F epoxy resin manufactured by Nippon Steel & Sumikin Materials Co., Ltd.); “EX-721” (glycidyl ester epoxy resin manufactured by Nagase ChemteX Corp.); “CEL-2021P” (alicyclic epoxy resin having an ester skeleton manufactured by Daicel Corp.); “PB-3600” (epoxy resin having a butadiene structure manufactured by Daicel Corp.); “ZX1658” and “ZX1658GS” (both are liquid 1,4-glycidyl cyclohexane epoxy resins manufactured by Nippon Steel & Sumikin Materials Co., Ltd.); and “EP3950L” (glycidyl amine epoxy resin manufactured by ADEKA Corp.). These may be used alone or in combination of two or more kinds of thereof.

The solid epoxy resin is preferably a solid epoxy resin having three or more epoxy groups in one molecule thereof, while more preferably a solid epoxy resin of an aromatic type having three or more epoxy groups in one molecule thereof.

The solid epoxy resin is preferably a bixylenol epoxy resin, a naphthalene epoxy resin, a naphthalene 4-functional epoxy resin, a cresol novolak epoxy resin, a dicyclopentadiene epoxy resin, a trisphenol epoxy resin, a naphthol epoxy resin, a biphenyl epoxy resin, a naphthylene ether epoxy resin, an anthracene epoxy resin, a bisphenol A epoxy resin, a bisphenol AF epoxy resin, and a tetraphenylethane epoxy resin. The solid epoxy resin is more preferably a bisphenol AF epoxy resin, a biphenyl epoxy resin, and a bixylenol epoxy resin.

Specific examples of the solid epoxy resin include “HP4032H” (naphthalene epoxy resin manufactured by DIC Corp.); “HP-4700” and “HP-4710” (both are naphthalene four-functional epoxy resins manufactured by DIC Corp.); “N-690” (cresol novolak epoxy resin manufactured by DIC Corp.); “N-695” (cresol novolak epoxy resin manufactured by DIC Corp.); “HP-7200” (dicyclopentadiene epoxy resin manufactured by DIC Corp.); “HP-7200HH”, “HP-7200H”, “EXA-7311”, “EXA-7311-G3”, “EXA-7311-G4”, “EXA-7311-G4S”, and “HP6000” (all are naphthylene ether epoxy resins manufactured by DIC Corp.); “EPPN-502H” (trisphenol epoxy resin manufactured by Nippon Kayaku Co., Ltd.); “NC7000L” (naphthol novolak epoxy resin manufactured by Nippon Kayaku Co., Ltd.); “NC3000H”, “NC3000”, “NC3000L”, and “NC3100” (all are biphenyl epoxy resins manufactured by Nippon Kayaku Co., Ltd.); “ESN475V” (naphthol epoxy resin manufactured by Nippon Steel & Sumikin Materials Co., Ltd.); “ESN485” (naphthol novolak epoxy resin manufactured by Nippon Steel & Sumikin Materials Co., Ltd.); “YX4000H”, “YX4000”, and “YL6121” (all are biphenyl epoxy resins manufactured by Mitsubishi Chemical Corp.); “YX4000HK” (bixylenol epoxy resin manufactured by Mitsubishi Chemical Corp.); “YX8800” (anthracene epoxy resin manufactured by Mitsubishi Chemical Corp.); “PG-100” and “CG-500” (both are manufactured by Osaka Gas Chemicals Co., Ltd.); “YL7760” (bisphenol AF epoxy resin manufactured by Mitsubishi Chemical Corp.); “YL7800” (fluorene epoxy resin manufactured by Mitsubishi Chemical Corp.); “jER1010” (solid bisphenol A epoxy resin manufactured by Mitsubishi Chemical Corp.); and “jER1031S” (tetraphenylethane epoxy resin manufactured by Mitsubishi Chemical Corp.). These may be used alone or in combination of two or more of kinds thereof.

Here, the commercially available epoxy resin described above can include epichlorohydrin. Therefore, the commercially available epoxy resins are used usually after carrying out a purification treatment to remove epichlorohydrin. By so doing, the chloride ion content in the resin composition can be decreased. Examples of the purification treatment include distillation.

When the liquid epoxy resin and the solid epoxy resin are used in combination as the (A) epoxy resin, the mass ratio of thereof (liquid epoxy resin: solid epoxy resin) is preferably 1:1 to 1:20, more preferably 1:1.5 to 1:15, while especially preferably 1:2 to 1:10. When the mass ratio of the liquid epoxy resin to the solid epoxy resin is within the above-mentioned range, the intended effects of the present invention can be clearly obtained. Usually, when the resin composition is used in the form of a resin sheet, a suitable stickiness can be obtained. In addition, usually, when the resin composition is used in the form of a resin sheet, not only a sufficient flexibility can be obtained but also a handling property can be improved. Furthermore, usually, a cured product having a sufficient breaking strength can be obtained.

The epoxy equivalent of the (A) epoxy resin is preferably 50 to 5,000 g/eq, more preferably 50 to 3,000 g/eq, still more preferably 80 to 2,000 g/eq, while far more preferably 110 to 1,000 g/eq. Within this range, crosslink of the cured product in the resin composition layer is sufficiently dense so that the insulating layer having the surface roughness thereof lowered can be obtained. The epoxy equivalent is the mass of the epoxy resin having one equivalent epoxy group. The epoxy equivalent may be measured in accordance with JIS K7236.

In view of clearly obtaining the intended effects of the present invention, the weight-average molecular weight (Mw) of the (A) epoxy resin is preferably 100 to 5,000, more preferably 250 to 3,000, while still more preferably 400 to 1,500.

The weight-average molecular weight of a resin can be measured as the value in terms of polystyrene by means of a gel permeation chromatography (GPC) method.

In view of obtaining the insulating layer having excellent mechanical strength and insulation reliability, a content of the (A) epoxy resin is preferably 1% or more by mass, more preferably 3% or more by mass, while still more preferably 5% or more by mass, on the basis of 100% by mass of the non-volatile components in the resin composition. In view of clearly obtaining the intended effects of the present invention, the upper limit of the content of the epoxy resin is preferably 20% or less by mass, more preferably 15% or less by mass, while especially preferably 10% or less by mass. It must be noted that in the present invention the content of each component in the resin composition is based on 100% by mass of the non-volatile components in the resin composition unless otherwise specifically mentioned.

In view of making the chloride ion content in the resin composition to 50 ppm or less, usually, prior to preparation of the resin composition, it is preferable to remove epichlorohydrin, a main component in the impure substances in the (A) epoxy resin, by means of distillation of the (A) epoxy resin. The temperature, pressure, and so forth at the time of distillation of the (A) epoxy resin may be appropriately changed depending on the (A) epoxy resin.

### (B) Curing Agent

The resin composition contains (B) a curing agent as the (B) component. Usually, the (B) curing agent has a function to cure the resin composition by undergoing a reaction with the (A) component. The (B) curing agents may be used alone or in combination of two or more kinds thereof.

Examples of the (B) curing agent include an acid anhydride curing agent, an active ester curing agent, a phenol curing agent, a naphthol curing agent, a benzoxiazine curing agent, a cyanate ester curing agent, a carbodiimide curing agent, and an amine curing agent. Among them, in view of clearly obtaining the intended effects of the present invention, an acid anhydride curing agent is preferably included in the resin composition.

The acid anhydride curing agent can be a curing agent having one or more acid anhydride groups in one molecule thereof. Examples of the acid anhydride curing agent include phthalic acid anhydride, tetrahydrophthalic acid anhydride, hexahydrophthalic acid anhydride, methyl tetrahydrophthalic acid anhydride, methyl hexahydrophthalic acid anhydride, methyl nadic acid anhydride, hydrogenated methyl nadic acid anhydride, trialkyl tetrahydrophthalic acid anhydride, dodecenyl succinic acid anhydride, 5-(2,5-dioxotetrahydro-3-furanyl)-3-methyl-3-cyclohexene-1,2-dicarboxylic acid anhydride, trimellitic acid anhydride, pyromellitic acid anhydride, benzophenone tetracarboxylic acid dianhydride, biphenyl tetracarboxylic acid dianhydride, naphthalene tetracarboxylic acid dianhydride, oxydiphthalic acid dianhydride, 3,3′-4,4′-diphenylsulfone tetracarboxylic acid dianhydride, 1,3,3a,4,5,9b-hexahydro-5-(tetrahydro-2,5-dioxo-3-furanyl)-naphto[1,2-C]furane-1,3-dione, ethylene glycol bis(anhydrotrimellitate), and a polymer type acid anhydride such as a styrene-maleic acid resin, which is a copolymer of styrene and maleic acid.

Examples of the commercially available acid anhydride curing agent include “MH-700” manufactured by New Japan Chemical Co., Ltd.

As the active ester curing agent, compounds having one or more active ester groups in one molecule thereof can be used. Among the active ester curing agents like this, compounds having two or more highly reactive ester groups in one molecule thereof are preferable as the active ester curing agent, these including a phenol ester type, a thiophenol ester type, an N-hydroxyamine ester type, and a heterocyclic hydroxy compound ester type. The active ester curing agent is preferably the compound that is obtained by condensation reaction of a carboxylic acid compound and/or a thiocarboxylic acid compound with a hydroxy compound and/or a thiol compound. Especially, in view of enhancement of a heat resistance, an active ester curing agent obtained from a carboxylic acid compound and a hydroxy compound is preferable, while an active ester curing agent obtained from a carboxylic acid compound and a phenol compound and/or a naphthol compound is more preferable.

Examples of the carboxylic acid include benzoic acid, acetic acid, succinic acid, maleic acid, itaconic acid, phthalic acid, isophthalic acid, terephthalic acid, and pyromellitic acid.

Examples of the phenol compound or the naphthol compound include hydroquinone, resorcin, bisphenol A, bisphenol F, bisphenol S, phenolphthalin, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, fluoroglycin, benzene triol, dicyclopentadiene type diphenol compound, and phenol novolak. Here, “dicyclopentadiene type diphenol compound” means the diphenol compound obtained by condensation of one dicyclopentadiene molecule with two phenol molecules.

Specific examples of the preferable active ester curing agent include an active ester curing agent containing a dicyclopentadiene type diphenol structure, an active ester curing agent containing a naphthalene structure, an active ester curing agent containing an acetylated compound of phenol novolak, and an active ester curing agent containing a benzoylated compound of phenol novolak. Among them, the active ester curing agent containing a naphthalene structure and the active ester curing agent containing a dicyclopentadiene type diphenol structure are preferable. Here, “dicyclopentadiene type diphenol structure” means the divalent structure unit formed of phenylene-dicyclopentylene-phenylene.

Examples of the commercially available active ester curing agent include active ester curing agents containing a dicyclopentadiene type diphenol structure, such as “EXB9451”, “EXB9460”, “EXB9460S”, “HPC-8000-65T”, “HPC-8000H-65TM”, and “EXB-8000L-65TM” (all are manufactured by DIC Corp.); active ester curing agents containing a naphthalene structure, such as “EXB9416-70BK” and “EXB-8150-65T” (both are manufactured by DIC Corp.); active ester curing agents containing an acetylated compound of phenol novolak, such as “DC808” (manufactured by Mitsubishi Chemical Corp.); active ester curing agents containing a benzoylated compound of phenol novolak, such as “YLH1026” (manufactured by Mitsubishi Chemical Corp.); and active ester curing agents as a benzoylated compound of phenol novolak, such as “YLH1026” (manufactured by Mitsubishi Chemical Corp.), “YLH1030” (manufactured by Mitsubishi Chemical Corp.), and “YLH1048” (manufactured by Mitsubishi Chemical Corp.).

In view of the heat resistance and the water resistance, as the phenol curing agent and the naphthol curing agent, both having a novolak structure are preferable. In view of adhesion with a conductive layer, a nitrogen-containing phenol curing agent is preferable, while a phenol curing agent having a triazine skeleton is more preferable.

Specific examples of the phenol curing agent and the naphthol curing agent include “MEH-7700”, “MEH-7810”, and “MEH-7851” (all are manufactured by Meiwa Plastic Industries, Ltd.); “NHN”, “CBN”, and “GPH” (all are manufactured by Nippon Kayaku Co., Ltd.); “SN170”, “SN180”, “SN190”, “SN475”, “SN485”, “SN495”, “SN-495V”, and “SN375” (all are manufactured by Nippon Steel & Sumikin Materials Co., Ltd.); and “TD-2090”, “LA-7052”, “LA-7054”, “LA-1356”, “LA-3018-50P”, and “EXB-9500” (all are manufactured by DIC Corp.).

Specific examples of the benzoxazine curing agent include “JBZ-OD100” (benzoxazine ring equivalent of 218), “JBZ-OP100D” (benzoxazine ring equivalent of 218), and “ODA-BOZ” (benzoxazine ring equivalent of 218) (all are manufactured by JFE Chemical Corp.); “P-d” (benzoxazine ring equivalent of 217) and “F-a” (benzoxazine ring equivalent of 217) (both are manufactured by Shikoku Chemicals Corp.); and “HFB2006M” (benzoxazine ring equivalent of 432) (manufactured by Showa Highpolymer Co., Ltd.).

Examples of the cyanate ester curing agent include bifunctional cyanate resins such as bisphenol A dicyanate, polyphenol cyanate, oligo(3-methylene-1,5-phenylenecyanate), 4,4′-methylenebis(2,6-dimethylphenylcyanate), 4,4′-ethylidene diphenyl dicyanate, hexafluorobisphenol A dicyanate, 2,2-bis(4-cyanate)phenylpropane, 1,1-bis(4-cyanatephenylmethane), bis(4-cyanate-3,5-dimethylphenyl)methane, 1,3-bis(4-cyanatephenyl-1-(methylethylidene))benzene, bis(4-cyanatephenyl) thioether, and bis(4-cyanatephenyl) ether; polyfunctional cyanate resins derived from a phenol novolak, a cresol novolak, and the like; and a prepolymer in which these cyanate resins are partially made to triazine. Specific examples of the cyanate ester curing agent include “PT30” and “PT60” (both are phenol novolak polyfunctional cyanate ester resins); “ULL-950S” (polyfunctional cyanate ester); “BA230” and “BA230S75” (prepolymers in which part or all of bisphenol A dicyanate is made to triazine so as to be a trimer), all of these being manufactured by Lonza Japan Ltd.

Specific examples of the carbodiimide curing agent include Carbodilite (registered trade mark) V-03 (carbodiimide equivalent of 216), V-05 (carbodiimide equivalent of 262), V-07 (carbodiimide equivalent of 200), and V-09 (carbodiimide equivalent of 200) (all are manufactured by Nisshinbo Chemical, Inc.); and Stabaxol (registered trade mark) P (carbodiimide equivalent of 302, manufactured by Rhein Chemie GmbH).

The amine curing agent can be the curing agent having one or more amino groups in one molecule thereof. Examples thereof include an aliphatic amine, a polyether amine, an alicyclic amine, and an aromatic amine. Among them, in view of expressing the intended effects of the present invention, an aromatic amine is preferable. The amine curing agent is preferably a primary amine and a secondary amine, while a primary amine is more preferable. Specific examples of the amine curing agent include 4,4′-methylene bis(2,6-dimethylaniline), diphenyl diaminosulfone, 4,4′-diaminodiphenylmethane, 4,4′-diaminodiphenyl sulfone, 3,3′-diaminodiphenyl sulfone, m-phenylene diamine, m-xylylene diamine, diethyltoluene diamine, 4,4′-diaminodiphenyl ether, 3,3′-dimethyl-4,4′-diaminobiphenyl, 2,2′-dimethyl-4,4′-diaminobiphenyl, 3,3′-dihydroxybenzidine, 2,2-bis(3-amino-4-hydroxyphenyl)propane, 3,3-dimethyl-5,5-diethyl-4,4-diphenylmethane diamine, 2,2-bis(4-aminophenyl)propane, 2,2-bis(4-(4-aminophenoxy)phenyl)propane, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, bis(4-(4-aminophenoxy)phenyl) sulfone, and bis(4-(3-aminophenoxy)phenyl) sulfone. Commercially available amine curing agents may be used. Examples thereof include “KAYABOND C-200S”, “KAYABOND C-100”, “KAYAHARD A-A”, “KAYAHARD A-B”, and “KAYAHARD A-S” (all are manufactured by Nippon Kayaku Co. Ltd.), as well as “Epicure W” (manufactured by Mitsubishi Chemical Corp.).

The mass ratio of the (A) epoxy resin to the (B) curing agent, in terms of a ratio of (the total number of epoxy groups in the epoxy resin): (the total number of reactive groups in the curing agent), is preferably 1:0.01 to 1:10, more preferably 1:0.1 to 1:5, while still more preferably 1:1 to 1:3. Herein, the reactive group in the curing agent is an active hydroxy group and the like, which are different dependent on the curing agent. The total number of the epoxy groups in the epoxy resin is a value obtained by dividing the mass of the solid content in each epoxy resin by respective epoxy equivalent and summing the calculated values for all the epoxy resins. The total number of reactive groups in the curing agent is a value obtained by dividing the mass of the solid content in each curing agent by respective reactive group equivalent and summing the calculated values for all the curing agents. By setting the mass ratio of the epoxy resin to the curing agent, the heat resistance of the cured product of the resin composition can be further improved.

In view of clearly obtaining the intended effects of the present invention, the content of the (B) curing agent is, relative to 100% by mass of the non-volatile components in the resin composition, preferably 1% or more by mass, more preferably 2% or more by mass, while still more preferably 3% or more by mass; and it is preferably 10% or less by mass, more preferably 8% or less by mass, while still more preferably 5% or less by mass.

### (C) Inorganic Filler

The resin composition contains (C) an inorganic filler as the (C) component. When the (C) inorganic filler is used, the coefficient of a linear thermal expansion of the cured product of the resin composition can be lowered.

An inorganic compound is used as the inorganic filler. Examples of the inorganic filler include silica, alumina, glass, cordierite, silicon oxide, barium sulfate, barium carbonate, talc, clay, mica powder, zinc oxide, hydrotalcite, boehmite, aluminum hydroxide, magnesium hydroxide, calcium carbonate, magnesium carbonate, magnesium oxide, boron nitride, aluminum nitride, manganese nitride, aluminum borate, strontium carbonate, strontium titanate, calcium titanate, magnesium titanate, bismuth titanate, titanium oxide, zirconium oxide, barium titanate, barium titanate zirconate, barium zirconate, calcium zirconate, zirconium phosphate, and zirconium phosphate tungstate. Among them, calcium carbonate and silica are suitable, while silica is especially suitable. Examples of the silica include amorphous silica, fused silica, crystalline silica, synthesized silica, and hollow silica. Spherical silica is preferable as the silica. The (C) inorganic fillers may be used alone or in combination of two or more kinds thereof. Examples of the commercially available (C) component include “ST7030-20” (manufactured by Nippon Steel Chemical & Material Co., Ltd.); “MSS-6” and “AC-5V” (both are manufactured by Tatsumori Ltd.); “SP60-05” and “SP507-05” (both are manufactured by Nippon Steel & Sumikin Materials Co., Ltd.); “YC100C”, “YA050C”, “YA050C-MJE”, and “YA010C” (all are manufactured by Admatechs Co., Ltd.); “UFP-30”, “SFP-130MC”, “FB-7SDC”, “FB-SSDC”, and “FB-3SDC” (all are manufactured by Denka Co., Ltd.); “Silphil NSS-3N”, “Silphil NSS-4N”, and “Silphil NSS-5N” (all are manufactured by Tokuyama Corp.); and “SC2500SQ”, “SO-C4”, “SO-C2”, “SO-C1”, and “FE9” (all are manufactured by Admatechs Co., Ltd.).

Specific surface area of the (C) component is preferably 1 m²/g or more, more preferably 2 m²/g or more, while especially preferably 3 m²/g or more. There is no particular restriction in the upper limit thereof, although it is preferably 60 m²/g or less, more preferably 50 m²/g or less, or 40 m²/g or less. The specific surface area may be calculated by means of the BET multipoint method, in which a nitrogen gas is adsorbed onto the sample surface by using a specific surface area measurement apparatus (Macsorb HM-1210, manufactured by Mountech Co. Ltd.) in accordance with a BET method.

In view of clearly obtaining the intended effects of the present invention, the average particle diameter of the (C) component is preferably 0.01 μm or more, more preferably 0.05 μm or more, while still more preferably 0.1 μm or more; and it is preferably 20 μm or less, more preferably 15 μm or less, while still more preferably 10 μm or less.

The average particle diameter of the (C) component may be measured with a laser diffraction and scattering method based on the Mie scattering theory. Specifically, the particle diameter distribution of the inorganic filler on the volume basis is prepared by means of a laser diffraction scattering type particle diameter distribution measurement apparatus, and the average particle diameter thereof is measured from the median diameter thus obtained. The measurement sample is obtained by weighing 100 mg of the inorganic filler and 10 g of methyl ethyl ketone into a vial bottle, followed by dispersing this mixture for 10 minutes by means of an ultrasonic wave. The particle diameter distribution of the measurement sample of the (C) component on the volume basis is measured with a flow cell method using the light source wave lengths of blue and red lights by means of the laser diffraction type particle diameter distribution measurement apparatus; and the average particle diameter can be calculated as the median diameter from the particle diameter distribution thus obtained. Examples of the laser diffraction type particle diameter distribution measurement apparatus include “LA-960” manufactured by Horiba Ltd.

In view of enhancement of the humidity resistance and of the dispersion property, the (C) component is preferably treated with a surface treatment agent. Examples of the surface treatment agent include a vinyl silane coupling agent, a (meth)acryl coupling agent, a fluorine-containing silane coupling agent, an amino silane coupling agent, an epoxy silane coupling agent, a mercapto silane coupling agent, a silane coupling agent, an alkoxy silane, an organosilazane compound, and a titanate coupling agent. Among them, in view of clearly obtaining the intended effects of the present invention, a vinyl silane coupling agent, a (meth)acryl coupling agent, an amino silane coupling agent, an epoxy silane coupling agent, and a silane coupling agent are preferable, while an amino silane coupling agent, an epoxy silane coupling agent, and a silane coupling agent are more preferable. These surface treatment agents may be used alone or in combination of two or more kinds thereof.

Examples of the commercially available surface treatment agent include “KBM1003” (vinyl triethoxy silane, manufactured by Shin-Etsu Chemical Co., Ld.); “KBM503” (3-methacryloxy propyl triethoxy silane, manufactured by Shin-Etsu Chemical Co., Ld.); “KBM403” (3-glycidoxy propyl trimethoxy silane, manufactured by Shin-Etsu Chemical Co., Ld.), “KBM803” (3-mercaptopropyl trimethoxy silane, manufactured by Shin-Etsu Chemical Co., Ld.); “KBE903” (3-aminopropyl triethoxy silane, manufactured by Shin-Etsu Chemical Co., Ld.); “KBM573” (N-phenyl-3-aminopropyl trimethoxy silane, manufactured by Shin-Etsu Chemical Co., Ld.); “SZ-31” (hexamethyl disilazane, manufactured by Shin-Etsu Chemical Co., Ld.); “KBM103” (phenyl trimethoxy silane, manufactured by Shin-Etsu Chemical Co., Ld.); “KBM-4803” (long chain epoxy type silane coupling agent, manufactured by Shin-Etsu Chemical Co., Ld.); and “KBM-7103” (3,3,3-trifluoropropyl trimethoxy silane, manufactured by Shin-Etsu Chemical Co., Ld.).

In view of enhancement of the dispersion property of the inorganic filler, the degree of the surface treatment by means of the surface treatment agent is preferably within a prescribed range. Specifically, the inorganic filler is surface-modified preferably with 0.2 to 5 parts by mass, more preferably with 0.2 to 3 parts by mass, while still more preferably with 0.3 to 2 parts by mass of the surface treatment agent, relative to 100 parts by mass of the inorganic filler.

The degree of the surface treatment by the surface treatment agent may be evaluated by the carbon amount per unit surface area of the inorganic filler. In view of enhancement of the dispersion property of the inorganic filler, the carbon amount per unit surface area of the inorganic filler is preferably 0.02 mg/m² or more, more preferably 0.1 mg/m² or more, while still more preferably 0.2 mg/m² or more. On the other hand, in view of suppression of the increase in the melt viscosity of a resin varnish and in the melt viscosity in the sheet form, the carbon amount per unit surface area of the inorganic filler is preferably 1 mg/m² or less, more preferably 0.8 mg/m² or less, while still more preferably 0.5 mg/m² or less.

The carbon amount per unit surface area of the inorganic filler may be measured after the surface-treated inorganic filler is cleaned by a solvent (for example, methyl ethyl ketone (MEK)). Specifically, after sufficient amount of MEK as the solvent is added to the inorganic filler whose surface has been treated with a surface treatment agent, this is cleaned by means of an ultrasonic wave at 25° ° C. for 5 minutes. The supernatant solution thereof is removed; and then, after the solid component remained is dried, the carbon amount per unit surface area of the inorganic filler may be measured by using a carbon analysis apparatus. The carbon analysis apparatus such as “EMIA-320V” manufactured by Horiba Ltd. may be used.

In view of effectively lowering the coefficient of linear thermal expansion of the resin composition, a content of the (C) component (% by mass) is preferably 80% or more by mass, more preferably 83% or more by mass, while still more preferably 85% or more by mass; and it is preferably 95% or less by mass, more preferably 93% or less by mass, while still more preferably 90% or less by mass, on the basis of 100% by mass of the non-volatile components in the resin composition. In the present invention, even if a content of the inorganic filler in the resin composition is increased, adhesion after the HAST test can be retained; and thus, the decrease in the coefficient of thermal expansion and the increase in the adhesion with the conductive layer after the HAST test can be made compatible.

### (D) Curing Accelerator

The resin composition may contain (D) a curing accelerator as an arbitrary component. Examples of the curing accelerator include a phosphorous type curing accelerator, an amine type curing accelerator, an imidazole type curing accelerator, a guanidine type curing accelerator, and a metal type curing accelerator. Among them, an amine type curing accelerator and an imidazole type curing accelerator are preferable, while an amine type curing accelerator is more preferable. The curing accelerators may be used alone or in combination of two or more kinds thereof.

Examples of the phosphorous type curing accelerator include triphenyl phosphine, phosphonium borate compounds, tetraphenyl phosphonium tetraphenyl borate, n-butyl phosphonium tetraphenyl borate, tetrabutyl phosphonium decanoate salt, (4-methylphenyl)triphenyl phosphonium thiocyanate, tetraphenyl phosphonium thiocyanate, and butyl triphenyl phosphonium thiocyanate. Among them, triphenyl phosphine and tetrabutyl phosphonium decanoate salt are preferable.

Examples of the amine type curing accelerator include trialkyl amines such as triethyl amine and tributyl amine; and 4-dimethylaminopyridine, benzyl dimethyl amine, 2,4,6-tris(dimethylaminomethyl)phenol, and 1,8-diazabicyclo(5,4,0)-undecene. Among them, 4-dimethylaminopyridine and 1,8-diazabicyclo(5,4,0)-undecene are preferable.

Examples of the imidazole type curing accelerator include imidazole compounds such as 2-methyl imidazole, 2-undecyl imidazole, 2-heptadecyl imidazole, 1,2-dimethyl imidazole, 2-ethyl-4-methyl imidazole, 1,2-dimethyl imidazole, 2-ethyl-4-methyl imidazole, 2-phenyl imidazole, 2-phenyl-4-methyl imidazole, 1-bezyl-2-methyl imidazole, 1-benzyl-2-phenyl imidazole, 1-cyanoethyl-2-methyl imidazole, 1-cyanoethyl-2-undecyl imidazole, 1-cyanoethyl-2-ethyl-4-methyl imidazole, 1-cyanoethyl-2-phenyl imidazole, 1-cyanoethyl-2-undecyl imidazolium trimellitate, 1-cyanoethyl-2-phenyl imidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-metylimidazolyl-(1′)]-ethyl-s-triazine, 2,4-diamino-6-[2′-methylimidazolyl-(1′)]-ethyl-s-triazine isocyanuric acid adduct, 2-phenylimidazole isocyanuric acid adduct, 2-phenyl-4,5-dihydroxymethyl imidazole, 2-phenyl-4-methyl-5-hydroxymethyl imidazole, 2,3-dihydro-1H-pyrro[1,2-a]benzimidazole, 1-dodecyl-2-methyl-3-benzyl imidazolium chloride, 2-methyl imidazoline, and 2-phenyl imidazoline; and adducts of these imidazole compounds with an epoxy resin. Among them, 2-ethyl-4-methyl imidazole and 1-benzyl-2-phenyl imidazole are preferable.

Commercially available imidazole type curing accelerators may be used. Examples thereof include “P200-H50” manufactured by Mitsubishi Chemical Corp.

Examples of the guanidine type curing accelerator include dicyan diamide, 1-methyl guanidine, 1-ethyl guanidine, 1-cyclohexyl guanidine, 1-phenyl guanidine, 1-(o-tolyl) guanidine, dimethyl guanidine, diphenyl guanidine, trimethyl guanidine, tetramethyl guanidine, pentamethyl guanidine, 1,5,7-triazabicyclo[4.4.0]deca-5-ene, 7-methyl-1,5,7-triazabicyclo[4.4.0]deca-5-ene, 1-methyl biguanide, 1-ethyl biguanide, 1-n-butyl biguanide, 1-n-octadecyl biguanide, 1,1-dimethyl biguanide, 1,1-diethyl biguanide, 1-cyclohexyl biguanide, 1-allyl biguanide, 1-phenyl biguanide, and 1-(o-tolyl) biguanide. Among them, dicyan diamide and 1,5,7-triazabicyclo[4.4.0]deca-5-ene are preferable.

Examples of the metal type curing accelerator include organometallic complexes or organometallic salts of metals such as cobalt, copper, zinc, iron, nickel, manganese, and tin. Specific examples of the organometallic complex include organic cobalt complexes such as cobalt (II) acetylacetonate and cobalt (III) acetylacetonate; organic copper complexes such as copper (II) acetylacetonate; organic zinc complexes such as zinc (II) acetylacetonate; organic iron complexes such as iron (III) acetylacetonate; organic nickel complexes such as nickel (II) acetylacetonate; and organic manganese complexes such as manganese (II) acetylacetonate. Examples of the organometallic salt include zinc octylate, tin octylate, zinc naphthenate, cobalt naphthenate, tin stearate, and zinc stearate.

A content of the (C) curing accelerator is preferably 0.01% or more by mass, more preferably 0.03% or more by mass, while especially preferably 0.05% or more by mass; and it is preferably 3% or less by mass, more preferably 1% or less by mass, while especially preferably 0.5% or less by mass, on the basis of 100% by mass of the non-volatile components in the resin composition.

### (E) Other Additives

The resin composition may further include, in addition to the components mentioned above, other additives as arbitrary components. Examples of the other additive like this include resin additives such as a thermoplastic resin; a flame retardant; an organic filler; organometallic compounds such as an organic copper compound, an organic zinc compound, and an organic cobalt compound; a thickener; an antifoaming agent; a leveling agent; an adhesion assisting agent; a colorant; and a pigment. These other additives may be used alone or in combination of two or more of kinds thereof with an arbitrary ratio.

Examples of the colorant and the pigment include microparticles of melamine and organic bentonite; phthalocyanine blue; phthalocyanine green; iodine green; diazo yellow; crystal violet; titanium oxide; carbon black such as “MA-600MJ-S” manufactured by Mitsubishi Chemical Corp.; and naphthalene black.

A content of the colorant and the pigment is preferably 0.01% or more by mass, more preferably 0.05% or more by mass, while especially preferably 0.1% or more by mass; and it is preferably 3% or less by mass, more preferably 1% or less by mass, while especially preferably 0.5% or less by mass, on the basis of 100% by mass of the non-volatile components in the resin composition.

The resin composition mentioned above may contain a solvent if necessary, but the resin composition substantially not containing a solvent, that is, the non-solvent resin composition, is preferable. Even though the resin composition does not contain a solvent, this can be fluidized and nicely compression molded when this is molded by using a compression molding method. Therefore, the resin composition can be used as the non-solvent resin composition. The term “substantially not containing a solvent” means the content of the solvent is, for example, 1% or less by mass, relative to the entire non-solvent resin composition.

In view of clearly obtaining the intended effects of the present invention, it is preferable that the resin composition of the present invention does not contain a compound having a sulfur atom. A content of the compound having a sulfur atom is preferably less than 0.01%, more preferably 0.005% or less by mass, on the basis of 100% by mass of the non-volatile components in the resin composition.

### Production Method of the Resin Composition

The resin composition of the present invention can be produced, for example, by agitating a blended mixture by means of an agitation apparatus such as a rotary mixer. As described before, prior to preparation of the resin composition, it is preferable to remove epichlorohydrin, a main impurity in the (A) epoxy resin. It is also preferable to remove impure substances included in the (B) to (E) components, if necessary.

### Characteristics and Physical Properties of the Resin Composition

The resin composition of the present invention may be in a liquid state or in a solid state, but this is preferably in a liquid state at the time of molding thereof. For example, the resin composition in a liquid state at normal temperature (for example, 20° C.) may be molded by a compression molding method at normal temperature without any special temperature control, or may be molded by a compression molding method with heating to a suitable temperature. Alternatively, the resin composition in a liquid state at normal temperature may be filled in a cartridge, ejected from the cartridge, and then molded by a compression molding method. Usually, the resin composition in a solid state at normal temperature can become a liquid state by controlling the temperature thereof to a higher temperature (for example, 130° C.), so that by properly controlling the temperature with heating or the like, the composition can be molded by a compression molding method. Usually, the afore-mentioned resin compositions can become a liquid state at an appropriate temperature even without containing a solvent; and thus, this can be used as a liquid sealant.

Here, the term “the liquid state” means the state that the lowest melt viscosity of the resin composition is 4,000 poise or less. Specifically, the lowest melt viscosity of the resin composition is preferably 4,000 poise or less, more preferably 3,000 poise or less, while still more preferably 2,000 poise or less; and it is preferably 50 poise or more, more preferably 60 poise or more, while still more preferably 70 poise or more. Here, the term “lowest melt viscosity” means the lowest melt viscosity in the temperature range of 60 to 200° C. The lowest melt viscosity can be measured by using a dynamic viscoelasticity measurement apparatus. The lowest melt viscosity can be measured in accordance with the method described in Examples to be mentioned later.

The cured product that is obtained by curing the resin composition of the present invention at 180° C. for 90 minutes usually has a characteristic that the coefficient of thermal expansion thereof is low. Therefore, the cured product gives a sealing layer or an insulating layer having a low coefficient of thermal expansion. The coefficient of thermal expansion thereof is preferably 15 ppm or less, more preferably 10 ppm or less, while still more preferably 9 ppm or less. On the other hand, the lower limit value of the coefficient of thermal expansion thereof can be made to, such as for example, 1 ppm or more. The coefficient of thermal expansion thereof can be measured in accordance with the method described in Examples to be mentioned later.

The cured product obtained by curing the resin composition of the present invention at 180° C. for 90 minutes has a characteristic that the adhesion with copper after the HAST test is excellent because the shear strength with copper after the HAST test is high. Therefore, the cured product gives a sealing layer or an insulating layer having excellent adhesion with copper after the HAST test. The shear strength thereof after the HAST test is preferably 0.5 kgf/mm² or more, more preferably 0.6 kgf/mm² or more, while still more preferably 0.7 kgf/mm² or more. On the other hand, the upper limit value of the shear strength can be made to, such as for example, 10 kgf/mm² or less. Evaluation of the adhesion with copper after the HAST test can be carried out in accordance with the method described in Examples to be mentioned later.

The chloride ion content in the resin composition of the present invention is 50 ppm or less, preferably 40 ppm or less, while more preferably 30 ppm or less, or 25 ppm or less. When the chloride ion content therein is within this range, the cured product having excellent adhesion with the conductive layer even after the HAST test can be obtained. The lower limit value of the chloride ion content is not particularly restricted, while it can be made to 0 ppm or more, or such as for example 0.1 ppm or more. The chloride ion content is obtained by measurement in accordance with the sample combustion ion chromatography method (BS EN 14582 2007).

The resin composition has the characteristics described above so that this can be suitably used as the resin composition to seal electronic devices such as an organic EL device and a semiconductor (resin composition for sealing), especially as the resin composition to seal a semiconductor (resin composition for sealing of a semiconductor), preferably as the resin composition to seal a semiconductor chip (resin composition for sealing of a semiconductor chip). In addition, besides the sealant use, the resin composition may be suitably used as the resin composition for an insulating layer. For example, the resin composition may be suitably used to form an insulating layer of a semiconductor chip package (resin composition for insulating layer of a semiconductor chip package) and to form an insulating layer of a circuit board (including printed wiring board) (resin composition for insulating layer of a circuit board).

Examples of the semiconductor chip package include an FC-CSP, an MIS-BGA package, an ETS-BGA package, a Fan-out type WLP (Wafer Level Package), a Fan-in type WLP, a Fan-out type PLP (Panel Level Package), and a Fan-in type PLP.

The resin composition may also be used as an under filling material. For example, this may be used as the material for MUF (Molding Under Filling) that is used after a semiconductor chip is connected to a substrate.

In addition, the resin composition may be widely used in the fields using a resin composition such as a resin sheet, a sheet-form laminate material such as a prepreg, a solder resist, a die bonding material, a hole-filling resin, and a component-burying resin.

### Resin Sheet

The resin sheet of the present invention includes a support and a resin composition layer formed on the support. The resin composition layer includes a layer that contains the resin composition of the present invention, usually this layer being formed of the resin composition.

In view of reducing the thickness of the print wiring board, thickness of the resin composition layer is preferably 600 μm or less, more preferably 550 μm or less, while still more preferably 500 μm or less, as well as 400 μm or less, 350 μm or less, 300 μm or less, or 200 μm or less. The lower limit of the thickness of the resin composition layer is not particularly restricted, while, for example, it can be 1 μm or more, 5 μm or more, 10 μm or more, or the like.

Examples of the support include a film formed of a plastic material, metal foil, and a releasing paper. Among them, metal foil and a film formed of a plastic material are preferable.

When the film formed of a plastic material is used as the support, Examples of the plastic material include polyesters such as polyethylene terephthalate (hereinafter, sometimes this is simply called “PET”) and polyethylene naphthalate (hereinafter, sometimes this is simply called “PEN”); polycarbonate (hereinafter, sometimes this is simply called “PC”); acryl polymers such as polymethyl methacrylate (hereinafter, sometimes this is simply called “PMMA”); a cyclic polyolefin; triacetyl cellulose (hereinafter, sometimes this is simply called “TAC”); polyether sulfide (hereinafter, sometimes this is simply called “PES”); polyether ketone; and polyimide. Among them, polyethylene terephthalate and polyethylene naphthalate are preferable, while cheap polyethylene terephthalate is especially preferable.

When the metal foil is used as the support, Examples of the metal foil include copper foil and aluminum foil. Among them, copper foil is preferable. As to the copper foil, the foil formed of a copper single metal or an alloy of copper with other metal (for example, tin, chromium, silver, magnesium, nickel, zirconium, silicon, titanium, or the like) may be used.

The support may be subjected to a treatment such as a mat treatment, a corona treatment, or an antistatic treatment on the surface to be bonded with the resin composition layer.

As to the support, a releasing layer-attached support having a releasing layer on the surface to be bonded with the resin composition layer may be used. The releasing agent used in the releasing layer of the releasing layer-attached support may be one or more releasing agents selected from the group consisting of, for example, an alkyd resin, a polyolefin resin, a urethane resin, and a silicone resin. Examples of the releasing agent that is commercially available include “SK-1”, “AL-5”, and “AL-7”, all being manufactured by Lintech Corp. Examples of the releasing layer-attached supporting body include “Lumirror T60” manufactured by Toray Industries; “Purex” manufactured by Teijin Ltd.; and “Unipeel” manufactured by Unitika Ltd.

The thickness of the support is preferably in the range of 5 to 75 μm, while more preferably in the range of 10 to 60 μm. When the releasing layer-attached support is used, total thickness of the releasing layer-attached support is preferably within this range.

The resin sheet may be produced, for example, by applying the resin composition onto the support by using an application apparatus such as a die coater. If necessary, the resin composition is dissolved into an organic solvent to prepare a resin varnish; and then, the resin sheet may be produced by applying this resin varnish. Viscosity of the resin varnish may be controlled by using a solvent so as to improve applicability thereof. In the case that the resin varnish is used, usually, the resin varnish is dried after the application thereof so as to form the resin composition layer.

Examples of the organic solvent include ketone solvents such as acetone, methyl ethyl ketone, and cyclohexanone; acetate ester solvents such as ethyl acetate, butyl acetate, cellosolve acetate, propylene glycol monomethyl ether acetate, and carbitol acetate; carbitol solvents such as cellosolve and butyl carbitol; aromatic hydrocarbon solvents such as toluene and xylene; and amide solvents such as dimethyl formamide, dimethyl acetamide (DMAc), and N-methyl pyrrolidone. The organic solvent may be used singly or as a combination of two or more of them with an arbitrary ratio.

Drying may be carried out by a known methods such as heating or blowing of a hot air. The drying is carried out under drying conditions so as to make the content of the organic solvent in the resin composition layer to usually 10% or less by mass, while preferably 5% or less by mass. When the resin varnish containing an organic solvent with the amount of, for example, 30 to 60% by mass, is used, the resin composition layer may be formed by drying thereof at 50 to 150° C. for 3 to 10 minutes, although these conditions are different depending on the boiling point of the organic solvent in the resin varnish.

The resin sheet may include, if necessary, an arbitrary layer other than the support and the resin composition layer. For example, in the resin sheet, a protection film similar to the support may be formed on the surface of the resin composition layer not bonded to the support (namely, on the surface opposite to the support). Thickness of the protection film is, for example, 1 to 40 μm. Due to the protection film, the surface of the resin composition layer may be prevented from attachment of dirt and the like as well as from a scar. In the case that the resin sheet has the protection film, the resin sheet can be used after the protection film is removed. The resin sheet can be rolled up so as to be stored.

The resin sheet can be suitably used to form an insulating layer in production of a semiconductor chip package (resin sheet for insulation of a semiconductor chip package). For example, the resin sheet may be used to form an insulating layer of a circuit board (resin sheet for insulation of a circuit board). The FC-CSP, the MIS-BGA package, and the ETS-BGA package may be mentioned as the examples of the package using the substrate like this.

In addition, the resin sheet can be suitably used to seal a semiconductor chip (resin sheet for sealing of a semiconductor chip). Examples of the semiconductor chip package to which this resin sheet is applicable include the Fan-out type WLP, the Fan-in type WLP, the Fan-out type PLP, and the Fan-in type PLP.

In addition, the resin sheet may be used in the MUF material to be used after a semiconductor chip is connected to a substrate.

In addition, the resin sheet can be widely used in other fields in which a high insulation reliability is required. For example, the resin sheet can be used to form an insulating layer of a circuit board such as a printed wiring board.

### Circuit Board

The circuit board of the present invention includes an insulating layer formed of a cured product of the resin composition of the present invention. This circuit board may be produced, for example, by a production method including a process (1) and a process (2) as described below.

(1) A process to form a resin composition layer on a substrate.

(2) A process to thermally cure the resin composition layer so as to form an insulating layer.

At the process (1), a substrate is prepared. Examples of the substrate include a glass epoxy substrate, a metal substrate (a stainless steel, a cold roll steel plate (SPCC), or the like), a polyester substrate, a polyimide substrate, a BT resin substrate, and a thermosetting polyphenylene ether substrate. The substrate may have, as a part of the substrate, a metal layer such as copper foil on the surface thereof. For example, a substrate having on both surfaces thereof a first metal layer and a second metal layer, the layers being removable, may be used. In the case that the substrate like this is used, usually, a conductive layer as a wiring layer capable of functioning as a circuit wiring is formed on the surface of the second metal layer opposite to the first metal layer. Examples of the material of the metal layer include copper foil, copper foil attached with a carrier, and a material of the conductive layer to be mentioned later. Among them, copper foil is preferable. Commercially available substrates may be used as the substrate having the metal layer like this. Examples thereof include extremely thin copper foil attached with a carrier copper foil (“Micro Thin”, manufactured by Mitsui Mining & Smelting Co., Ltd.).

The conductive layer may be formed on one surface or both surfaces of the substrate. In the explanation hereinafter, the component including the conductive layer formed on the substrate surface is sometimes called “substrate attached with a wiring layer”. Examples of the conductive material that is included in the conductive layer include one or more metals selected from the group consisting of gold, platinum, palladium, silver, copper, aluminum, cobalt, chromium, zinc, nickel, titanium, tungsten, iron, tin, and indium. The conductive material formed of a single metal or of a metal alloy may be used. Examples of the metal alloy include metal alloys of two or more metals selected from the group mentioned above (for example, nickel-chromium alloy, copper-nickel alloy, and copper-titanium alloy). Among them, in view of general applicability to formation of the conductive layer, cost, and easy patterning, preferable are chromium, nickel, titanium, aluminum, zinc, gold, palladium, silver, or copper as the single metal; and nickel-chromium alloy, copper-nickel alloy, and copper-titanium alloy as the metal alloy. Among them, more preferable are chromium, nickel, titanium, aluminum, zinc, gold, palladium, silver, or copper, as the single metal, as well as nickel-chromium alloy. A single metal of copper is especially preferable.

In order to function, for example, as the wiring layer, the conductive layer may be pattern-processed. At this time, there is no particular restriction in the ratio of the line (circuit width)/space (width between the circuits) in the conductive layer, although the ratio is preferably 20/20 μm or less (namely, pitch is 40 μmm or less), more preferably 10/10 μm or less, still more 5/5 μm or less, far more preferably 1/1 μm or less, while especially preferably 0.5/0.5 μm or less. The pitch is not necessary the same in the entire conductive layer. The minimum pitch of the conductive layer may be, for example, 40 m or less, 36 μm or less, or 30 μm or less.

The thickness of the conductive layer is preferably 3 to 35 μm, more preferably 5 to 30 μm, still more preferably 10 to 20 μm, while especially preferably 15 to 20 μm, although this is dependent on the design of the circuit board.

The conductive layer may be formed, for example, by the method that includes a process to laminate a dry film (photosensitive resist film) onto a substrate, a process to irradiate the dry film by using a photomask followed by development thereof under prescribed conditions to obtain a patterned dry film, a process to form a conductive layer by a plating method such as an electrolysis plating method using, as a plating mask, the patterned dry film obtained by development, and a process to remove the patterned dry film. As to the dry film, a photosensitive dry film formed of a photoresist composition may be used. For example, the dry film formed of a resin such as a novolak resin or an acryl resin may be used. The lamination condition between the substrate and the dry film can be the same as the lamination condition between the substrate and the resin sheet to be mentioned later. Removal of the dry film may be carried out by using an alkaline delamination solution such as a sodium hydroxide solution.

After the substrate is prepared, the resin composition layer is formed on the substrate. In the case that the conductive layer is formed on the substrate surface, it is preferable that the resin composition layer be formed in such a way that the conductive layer may be buried into the resin composition layer.

The resin composition layer is formed, for example, by laminating the resin sheet to the substrate. The lamination may be carried out, for example, by hot-pressing the resin sheet to the substrate from the support side thereof so as to bind the resin composition layer to the substrate. Examples of the component for hot-pressing of the resin sheet to the substrate (hereinafter, this component is sometimes called “hot-pressing component”) include a heated metal plate (SUS mirror plate, or the like) and a heated metal roll (SUS roll, or the like). At this time, it is preferable that the resin sheet not be pressed directly with the hot-pressing component but be pressed via an elastic material such as a heat-resistant rubber so that the resin sheet may sufficiently follow the surface irregularity of the substrate.

Lamination of the resin sheet to the substrate may be carried out, for example, by a vacuum lamination method. In the vacuum lamination method, the temperature of hot pressing is preferably 60 to 160° C., while more preferably 80 to 140° C. The pressure of hot pressing is preferably 0.098 to 1.77 MPa, while more preferably 0.29 to 1.47 MPa. The period of hot pressing is preferably 20 to 400 seconds, while more preferably 30 to 300 seconds. The lamination is carried out under evacuated condition of preferably 13 hPa or less of the pressure.

After the lamination, for example, the laminated resin sheet may be flattened by pressing the hot-pressing component from the side of the support under a normal pressure (under an atmospheric pressure). The pressing conditions of the flattening process can be as same as the before-mentioned hot pressing conditions in the lamination. The lamination and the flattening process may be carried out continuously by using a vacuum laminator.

The resin composition layer may be formed, for example, by a compression molding method. In the specific operation of the compression molding method, for example, an upper mold and a lower mold are prepared as the mold thereof. The resin composition is applied onto a substrate. The substrate thus applied with the resin composition is placed on the lower mold. Then, the upper mold and the lower mold are clamped together, and then, a heat and a pressure are applied to the resin composition to carry out the compression molding.

Alternatively, specific operation of the compression molding method may be carried out, for example, as follows. An upper mold and a lower mold are prepared as the molds for the compression molding. The resin composition is placed on the lower mold. The substrate is attached to the upper mold. Then, the upper mold and the lower mold are clamped together in such a way that the resin composition placed on the lower mold may contact with the substrate attached to the upper mold, and then, a heat and a pressure are applied to carry out the compression molding.

The molding conditions in the compression molding method are different depending on the composition of the resin composition. The temperature of the mold at the time of molding is preferably the temperature at which the resin composition can express excellent compression moldability, and thus, for example, the temperature is preferably 80° C. or higher, more preferably 100° C. or higher, while still more preferably 120° C. or higher; and it is preferably 200° C. or lower, more preferably 170° C. or lower, while still more preferably 150° C. or lower. The pressure applied at the time of molding is preferably 1 MPa or more, more preferably 3 MPa or more, while still more preferably 5 MPa or more; and it is preferably 50 MPa or lower, more preferably 30 MPa or lower, while still more preferably 20 MPa or lower. The curing period is preferably 1 minute or longer, more preferably 2 minutes or longer, while especially preferably 5 minutes or longer; and it is preferably 60 minutes or shorter, more preferably 30 minutes or shorter, while especially preferably 20 minutes or shorter. Usually, after molding of the resin composition layer, the molds are removed. Removal of the molds may be carried out before or after thermal curing of the resin composition layer.

After the resin composition layer is formed on the substrate, the resin composition layer is thermally cured to form the insulating layer. Thermal curing conditions of the resin composition layer are different depending on the resin composition. The curing temperature is usually in the range of 120 to 240° C. (preferably in the range of 150 to 220° C., while more preferably in the range of 170 to 200° C.), and the curing time is in the range of 5 to 120 minutes (preferably in the range of 10 to 100 minutes, while more preferably in the range of 15 to 90 minutes).

Before the resin composition layer is thermally cured, the resin composition layer may be pre-heated at the temperature lower than the curing temperature. For example, prior to thermal curing of the resin composition layer, the resin composition layer may be pre-heated at the temperature of usually 50° C. or higher and lower than 120° C. (preferably 60° C. or higher and 110° C. or lower, while more preferably 70° C. or higher and 100° C. or lower) and for the period of usually 5 minutes or longer (preferably 5 to 150 minutes, while more preferably 15 to 120 minutes).

In the way as described above, the circuit board having the insulating layer can be produced. The production method of the circuit board may further include an arbitrary process.

For example, in the case that the circuit board is produced by using the resin sheet, the production method of the circuit board may include a process of removal of the support of the resin sheet. The support may be removed before or after thermal curing of the resin composition layer.

The production method of the circuit board may include, for example, a process to polish the surface of the insulating layer after the insulating layer is formed. The polishing method is not particularly restricted. For example, the surface of the insulating layer may be polished by using a plane grinder.

The production method of the circuit board may include, for example, a process (3) of interlayer connection to connect between the conductive layers, so called a process to make a hole in the insulating layer. With this, a hole such as a via hole and a through hole may be formed in the insulating layer. Examples of the method to form a via hole include methods using laser irradiation, etching, and mechanical drilling. The size and shape of the via hole may be appropriately determined in accordance with a design of the circuit board. At the process (3), the interlayer connection may be carried out by polishing or grinding of the insulating layer.

After the via hole is formed, it is preferable to carry out a process to remove a smear in the via hole. This process is sometimes called a desmearing process. For example, in the case that formation of the conductive layer on the insulating layer is carried out with a plating process, the desmearing process to the via hole may be carried out with a wet method. In the case that formation of the conductive layer on the insulating layer is carried out with a sputtering process, the desmearing process may be carried out with a dry method such as a plasma treatment process. By the desmearing process, a roughening treatment may be done in the insulating layer.

Before the conductive layer is formed on the insulating layer, the roughening treatment may be done in the insulating layer. With this roughening treatment, usually, the surface of the insulating layer including inside the via hole is roughened. The roughening treatment may be carried out with any of a dry method and a wet method. Examples of the roughening treatment with a dry method include a plasma treatment. The roughening process with a wet process may be carried out, for example, by a method in which a swelling treatment with a swelling liquid, a roughening treatment with an oxidant, and a neutralizing treatment with a neutralizing solution are carried out in this order.

After the via hole is formed, the conductive layer is formed on the insulating layer. By forming the conductive layer at the position where the via hole is formed, the newly formed conductive layer and the conductive layer on the substrate surface are conductively connected thereby achieving the interlayer connection. Examples of the method for forming the conductive layer include a plating method, a sputtering method, and a vapor deposition method. Among them, a plating method is preferable. In a preferable embodiment, the surface of the insulating layer is plated with a suitable method such as a semi-additive method or a full additive method so as to form the conductive layer having an intended wiring pattern. In the case that the support in the resin sheet is metal foil, the conductive layer having an intended wiring pattern may be formed by a subtractive method. The material of the conductive layer to be formed may be a single metal or a metal alloy. The conductive layer may have a single layer structure or a multiple layer structure including two or more layers of different materials.

Here, an exemplary embodiment for forming the conductive layer onto the insulating layer will be explained in detail. A plated seed layer is formed onto the surface of the insulating layer by electroless plating. Next, onto the plated seed layer thus formed, an intended mask pattern is formed so as to expose part of the plated seed layer in accordance with an intended wiring pattern. After an electrolytically plated layer is formed by electrolytic plating onto the exposed plated seed layer, the mask pattern is removed. Thereafter, the conductive layer having the intended wiring pattern can be formed by removing the unnecessary plated seed layer with etching or the like. Here, at the time of forming the conductive layer, a dry film that is used for forming the mask pattern is the same as the dry film mentioned before.

The production method of the circuit board may include a process (4) to remove the substrate. By removing the substrate, the circuit board having the insulating layer and the conductive layer buried into this insulating layer can be obtained. This process (4) may be carried out, for example, when the substrate having removable metal foil is used.

### Semiconductor Chip Package

The semiconductor chip package relating to a first embodiment of the present invention includes the circuit board mentioned above and a semiconductor chip installed on this circuit board. This semiconductor chip package can be produced by bonding a semiconductor chip with the circuit board.

The bonding condition of the circuit board with the semiconductor chip may be arbitrarily chosen from those that can conductively connect between the terminal electrode of the semiconductor chip and the circuit wiring of the circuit board. For example, the condition used in installation of the flip chip of the semiconductor chip may be used. In addition, for example, the semiconductor chip and the circuit board may be bonded via an insulating adhesive.

For example, the bonding method may be carried out by a method for press adhesion of the semiconductor chip to the circuit board. Conditions of the press adhesion are usually in the range of 120 to 240° C. as the press adhesion temperature (preferably in the range of 130 to 200° C., while more preferably in the range of 140 to 180° C.) and usually in the range of 1 to 60 seconds as the press adhesion time (preferably in the range of 5 to 30 seconds).

Alternative examples of the bonding method include the method with which the semiconductor chip is reflow-bonded with the circuit board. The temperature in the reflow condition may be in the range of 120 to 300° C.

After the semiconductor chip is bonded with the circuit board, the semiconductor chip may be filled with a mold under fill material. As to the mold under fill material, the resin composition or the resin sheet as mentioned above may be used.

The semiconductor chip package relating to a second embodiment of the present invention includes the semiconductor chip and the cured product of the resin composition to seal this semiconductor chip. In the semiconductor chip package like this, usually, the cured product of the resin composition functions as a sealing layer. Examples of the semiconductor chip package relating to the second embodiment include the Fan-out type WLP.

The production method of the semiconductor chip package such as the Fan-out type WLP like this includes:

(A) a process to laminate a temporary fixing film to a substrate;

(B) a process to temporarily fix a semiconductor chip onto the temporary fixing film;

(C) a process to laminate the resin composition layer in the resin sheet of the present invention onto the semiconductor chip or to apply the resin composition of the present invention onto the semiconductor chip, followed by thermally curing the resin composition so as to form a sealing layer;

(D) a process to remove the substrate and the temporary fixing film from the semiconductor chip;

(E) a process to form a rewire-forming layer (insulating layer) onto the surface from which the substrate of the semiconductor chip and the temporary fixing film are removed;

(F) a process to form a conductive layer (rewiring layer) onto the rewire-forming layer (insulating layer); and

(G) a process to form a solder resist layer onto the conductive layer. In addition, the production method of the semiconductor chip package can include (H) a process to individualize a plurality of the semiconductor chip packages into individual semiconductor chip packages by dicing.

Details of the production method of the semiconductor chip package as described above may be referred in the paragraphs 0066 to 0081 of International Patent Laid-Open Publication No. 2016/035577, which is incorporated herein by reference in its entirety.

The semiconductor chip package relating a third embodiment of the present invention is, for example, in the semiconductor chip package of the second embodiment, the semiconductor chip package in which the rewire-forming layer or the solder resist layer is formed by the cured product of the resin composition of the present invention.

### Semiconductor Device

Examples of the semiconductor device installed with the semiconductor chip package described above include various semiconductor devices to be supplied to electric products (for example, computer, cell phone, smart phone, tablet type device, wearable device, digital camera, medical equipment, and television) and to vehicles (for example, motor bike, automobile, train, marine ship, and airplane).

Other features of the invention will become apparent in the course of the following descriptions of exemplary embodiments which are given for illustration of the invention and are not intended to be limiting thereof.

### EXAMPLES

In the explanation below, “ppm”, “parts”, and “%”, which express quantities, are on the mass basis unless otherwise specifically mentioned. The operations explained hereinafter were carried out under normal temperature and normal pressure unless otherwise specifically mentioned.

The epoxy resins used in the Examples were used after the commercially purchased resin was purified by distillation. Silica A, Silica B, and Silica C used in Examples and Comparative Example are as follows.

Silica A: average particle diameter of 9.2 μm and specific surface area of 3.3 m²/g, surface of which is treated with KBM 573 (N-phenyl-3-aminopropyl trimethoxy silane, manufactured by Shin-Etsu Chemical Co., Ld.).

Silica B: average particle diameter of 8.5 μm and specific surface area of 3.2 m²/g, surface of which is treated with KBM 403 (3-glycidoxypropyl trimethoxy silane, manufactured by Shin-Etsu Chemical Co., Ld.).

Silica C: average particle diameter of 9.6 μm and specific surface area of 2.9 m²/g, surface of which is treated with KBM 4803 (long chain epoxy type silane coupling agent, manufactured by Shin-Etsu Chemical Co., Ld.).

### Example 1

A mixture of 5 parts of a glycidyl amine type epoxy resin (epoxy equivalent of 95 g/eq.), 5 parts of a bisphenol type epoxy resin (1:1 mixture of bisphenol A type and bisphenol F type; epoxy equivalent of 169 g/eq.), 7 parts of an acid anhydride curing agent (“MH-700”; acid anhydride equivalent of 164 g/eq., manufactured by New Japan Chemical Co., Ltd.), 140 parts of Silica A, 0.1 part of a curing accelerator (“1B2PZ”: 1-benzyl-2-phenyl imidazole, manufactured by Shikoku Chemicals Corp.), and 0.6 part of carbon black (“MA-600MJ-S”, manufactured by Mitsubishi Chemical Corp.) was uniformly dispersed by means of a mixer to obtain Resin Composition 1.

### Example 2

Resin Composition 2 was prepared in the same manner as Example 1 except Silica A was replaced by Silica B.

### Example 3

Resin Composition 3 was prepared in the same manner as Example 1 except Silica A was replaced by Silica C.

### Example 4

Resin Composition 4 was prepared in the same manner as Example 1 except 3 parts of an alicyclic epoxy resin (epoxy equivalent of 136 g/eq.) was additionally used.

### Comparative Example 1

Resin Composition 5 was prepared in the same manner as Example 1, except:

5 parts of the glycidyl amine type epoxy resin (epoxy equivalent of 95 g/eq.) was changed to 5 parts of the glycidyl amine type epoxy resin (“630”: epoxy equivalent of 95 g/eq., manufactured by Mitsubishi Chemical Corp.), and 5 parts of the bisphenol type epoxy resin (1:1 mixture of bisphenol A type and bisphenol F type; epoxy equivalent of 169 g/eq.) was changed to 5 parts of bisphenol F type epoxy (“EX-211”: epoxy equivalent of 138 g/eq., manufactured by Nagase ChemteX Corp.).

In Comparative Example 1, commercially purchased “630” and “EX-211” were used as they were without being distilled.

### Measurement of Chloride Ion Content

The chloride ion contents of Resin Compositions 1 to 5 prepared in Examples 1 to 4 and Comparative Example 1 were measured with a sample combustion ion chromatography method (in accordance with BS EN 14582 2007).

### Measurement of Coefficient of Thermal Expansion (CTE)

Resin Compositions 1 to 5 each prepared in the Examples and the Comparative Example was compression molded onto a release-treated 12-inch silicon wafer by using a compression molding apparatus (mold temperature of 130° C., pressure of 6 MPa, and curing period of 10 minutes) to obtain the resin composition layer having thickness of 300 μm. Then, the resin composition layer was removed from the release-treated silicon wafer, and then, the resin composition layer was thermally cured by heating at 180° C. for 90 minutes to obtain a cured sample. The cured sample was cut to the width of 5 mm and the length of 15 mm to obtain a specimen. This specimen was subjected to a thermal mechanical analysis with a tensile load method by using a thermal mechanical analysis apparatus (“ThermoPlus TMA8310, manufactured by Rigaku Corp.). Specifically, after the specimen was attached to the thermal mechanical analysis apparatus, it was continuously measured twice with the load of 1 g and the temperature raising rate of 5° C./minute as the measurement conditions. In the second measurement, the coefficient of thermal expansion (ppm/° C.) in a plane direction in the temperature range of 25 to 150° C. was calculated.

Measurement of lowest Melt Viscosity

The lowest melt viscosity of Resin Compositions 1 to 5 each prepared in the Examples and the Comparative Example was measured by using a dynamic viscoelasticity measurement apparatus (“Rheosol-G3000”, manufactured by UBM Co., Ltd.). The dynamic viscoelasticity of 1 g of the resin composition sample was measured by using parallel plates having the diameter of 18 mm with the temperature raising rate of 5° C./minute from the measurement start temperature of 60° C. till 200° C. and with the measurement temperature interval of 2.5° C., oscillation of 1 Hz, and distortion of 1 deg. as the measurement conditions to obtain the value of the lowest melt viscosity.

Evaluation of Copper Adhesion after HAST Test

A specimen of the resin composition, each prepared in the Examples and the Comparative Example, having the diameter of 4 mm and the thickness of 5 mm was prepared on the copper plane of a glass cloth based epoxy resin double-sided copper-cladded laminate (“R1515A”: copper foil having the thickness of 18 μm and substrate having the thickness of 0.4 mm, manufactured by Panasonic Corp.). Specifically, the resin composition was filled in a silicon rubber frame having the height of 4 mm obtained by hollowing out the silicon rubber so as to give a column shape having the height of 5 mm; then, after it was heated at 180° C. for 90 minutes, the silicon rubber frame was removed to obtain the specimen. After the specimen was subjected to the high temperature and high humidity environmental test (HAST) at 130° C. and 85% RH for 96 hours, the shear strength of the interface between the copper and the specimen in the position where the head position is 1 mm from the substrate by using a bond tester (series 4000, manufactured by Dage Corp.) with the head speed of 700 μm/s. The test was repeated for 5 times, and the average value thereof was obtained. When the shear strength was 0.5 kgf/mm² or more, it is marked by 0, and when the shear strength was less than 0.5 kgf/mm², it is marked by X.

The results are shown in Table 1.

TABLE 1

| | | | | | | Comparative |
|---|---|---|---|---|---|---|
| | | Example | | | | Example |
| | | 1 | 2 | 3 | 4 | 1 |
| (A) Component | Glycidyl amine epoxy resin | 5 | 5 | 5 | 5 | |
| | Bisphenol epoxy resin | 5 | 5 | 5 | 2 | |
| | Alicyclic epoxy resin | | | | 3 | |
| | 630 | | | | | 5 |
| | EX-211 | | | | | 5 |
| (B) Component | MH-700 | 7 | 7 | 7 | 7 | 7 |
| (C) Component | Silica A | 140 | | | 140 | 140 |
| | Silica B | | 140 | | | |
| | Silica C | | | 140 | | |
| (D) Component | 1B2PZ | 0.1 | 0.1 | 0.1 | 0.1 | 0.1 |
| (E) Component | MA-600MJ-S | 0.6 | 0.6 | 0.6 | 0.6 | 0.6 |

| | | | | | |
|---|---|---|---|---|---|
| Total of non-volatile components | 157.7 | 157.7 | 157.7 | 157.7 | 157.7 |
| Chloride ion content (ppm) | 19 | 20 | 19 | 10 | 110 |
| Coefficient of thermal expansion (ppm/• C.) | 7.40 | 8.10 | 6.60 | 7.00 | 10.00 |
| Lowest melt viscosity (poise) | 230 | 300 | 350 | 230 | 370 |
| Adhesion after HAST | ◯ | ◯ | ◯ | ◯ | X |

In Examples 1 to 4, even in the case that the (D) to (E) components were absent, it was confirmed that similar results to those in Examples described above could be obtained, although the results are different to some extent.

Where a numerical limit or range is stated herein, the endpoints are included. Also, all values and subranges within a numerical limit or range are specifically included as if explicitly written out.

As used herein the words “a” and “an” and the like carry the meaning of “one or more.”

Obviously, numerous modifications and variations of the present invention are possible in light of the above teachings. It is therefore to be understood that, within the scope of the appended claims, the invention may be practiced otherwise than as specifically described herein.

All patents and other references mentioned above are incorporated in full herein by this reference, the same as if set forth at length.

1. A resin composition comprising:
(A) at least one epoxy resin;
(B) at least one curing agent; and
(C) at least one inorganic filler, wherein
a chloride ion content included in the resin composition measured in accordance with a sample combustion ion chromatography method (BS EN 14582 2007) is 50 ppm or less.

2. The resin composition according to claim 1, which comprises (C) said at least one inorganic filler in an amount of 80% or more by mass when non-volatile components in the resin composition is taken as 100% by mass.

3. The resin composition according to claim 1, wherein coefficient of thermal expansion of a cured product obtained by thermally curing the resin composition at 180° C. for 90 minutes is 15 ppm or less.

4. The resin composition according to claim 1, wherein (B) said at least one curing agent comprises an acid anhydride curing agent.

5. The resin composition according to claim 1, wherein the resin composition is in a liquid state.

6. An insulating layer, which is sealed with a resin composition according to claim 1.

7. A circuit board, comprising an insulating layer formed of a cured product of the resin composition according to claim 1.

8. A semiconductor chip package, comprising a circuit board according to claim 7 and a semiconductor chip installed on said circuit board.

9. A semiconductor chip package, comprising a semiconductor chip and a cured product of the resin composition according to claim 1 which seals said semiconductor chip.
